(19) United States
(12) Patent Application Publication
(10) Pub. No.: US 2026/0182247 A1
(43) Pub. Date: Jun. 25, 2026

(54) Thermoelectric Heat Recovery

(71) Applicant: Saudi Arabian Oil Company, Dhahran (SA)

(72) Inventors: Mahdi A. Al-Dajani, Dammam (SA); Yousef D. Aloufi, Dhahran (SA); Ahmer Irshad, Dhahran (SA)

(21) Appl. No.: 19/001,474

(22) Filed: Dec. 25, 2024

(51) Int. Cl. H10N 10/13; E21B 36/02; H10N 10/17

(52) U.S. Cl. CPC H10N 10/13; E21B 36/025; H10N 10/17

(57) ABSTRACT

A thermoelectric heat recovery system is described. The thermoelectric heat recovery system includes a thermoelectric generator having a hot side and a cold side. The hot side of the thermoelectric generator is exposed to waste heat emitted by a flare from a well head. The thermoelectric heat recovery system also includes a heat sink coupled to the cold side of the thermoelectric generator. Electricity is generated by a temperature gradient across the thermoelectric generator.

### TECHNICAL FIELD

This disclosure relates generally to thermoelectric heat recovery.

### BACKGROUND

A flare, also known as a gas flare or flare stack, is a gas combustion device that burns flammable gases for disposal of the gases. The flare may be employed at oil or gas well sites or refining and chemical facilities during the production of hydrocarbons. During production flaring, some of the hydrocarbons discharged from the well are burned by the flare. Burning of the hydrocarbons produces heat and greenhouse gases.

### BRIEF DESCRIPTION OF DRAWINGS

FIG. 1 is an illustration of a production well.

FIG. 2 shows a thermoelectric heat recovery system.

FIG. 3 is a process flow diagram of a process that enables a thermoelectric heat recovery system.

### DETAILED DESCRIPTION

The present disclosure describes thermoelectric heat recovery. In some embodiments, at least one thermoelectric generator (TEG) obtains heat released by a flare. A TEG includes thermoelectric materials configured to realize a temperature gradient caused by the heat. The temperature gradient generates an electric voltage, and the generated voltage is converted into electrical power. The electrical power can be used immediately or stored for later use within a battery.

Thermoelectric heat recovery provides a reliable and consistent power source at a well site, which are often found in locations that are not easily accessible. As a result, moving and installing equipment, supplies, and personnel to and from well sites can be challenging and costly, as roads may be non-existent or in poor condition. The thermoelectric heat recovery system operates without moving parts, thereby reducing maintenance and increasing durability, and can adapt to varying heat outputs from flaring operations. Using a TEG to capture heat produced by flares reduces the need for traditional power sources, such as diesel generators. Moreover, thermoelectric heat recovery can reduce emissions from flares by capturing heat, resulting in sustainable and more environmentally friendly operations. Further, thermoelectric heat recovery increases the reliability of electrical systems at a well site and ensures continuous operation in even harsh environmental conditions. Accordingly, the thermoelectric heat recovery system is a sustainable solution that converts waste heat into a valuable resource and also contributes significantly to reducing the environmental impact of emissions by capturing and utilizing energy that would otherwise be lost to the atmosphere.

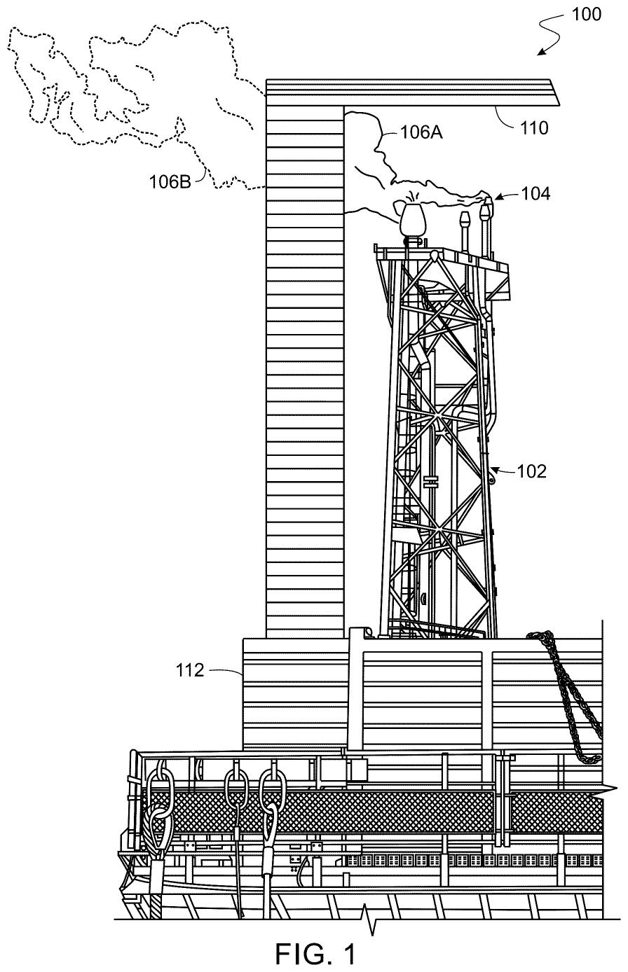

FIG. 1 is an illustration of a production well 100. The production well 100 has a well head 102 with several flare tips 104 being used to flare off waste gases resulting in waste heat 106A and 106B (collectively referred to as waste heat 106). Waste gases and heat occur, for example, during the production of hydrocarbons from the production well 100. In examples, the production well 100 is located at an onshore well site or an offshore well site. Offshore well sites may include a platform or rig. In examples, the production well 100 is drilled into a subterranean formation for the exploration or production of crude oil or natural gas.

In some embodiments, flares are used for production flaring where the hydrocarbons discharged from the well via the well head 102 are burned by the flare during production of the hydrocarbons. The hydrocarbons combusted during production flaring can include natural gas and liquid hydrocarbon (e.g., crude oil). In addition to production flaring, the flare may combust hydrocarbons collected during startup, maintenance, testing, or abnormal operations at the well site. The flare may also combust hydrocarbons discharged from the well via the well head 102 during flowback operations. Additionally, in industrial plants or facilities such as petroleum refineries, chemical plants, and natural gas processing plants, a flare may burn flammable gas released by pressure relief valves during unplanned over-pressuring of plant equipment. The flare in such facilities may also combust flammable vent gases during plant startups, plant shutdowns, and other plant operations typically for relatively short periods.

Flares due to production and flares in industrial plants or facilities generate heat from the flare. Flare temperatures can vary depending on the composition of the waste gas being flared. In the example of FIG. 1, a heat sink 110 captures heat created by flare tips 104. In some embodiments, the heat sink 110 is an air cooled heat sink. Additionally or alternatively, the heat sink 110 is a thermoelectric cooler that uses the Peltier effect to transfer heat from the flare.

A TEG 112 is positioned with a hot side is exposed to a heat source, such as the waste heat 106. A cold side of the TEG is coupled with the heat sink 110, creating a temperature gradient that causes electrons to move and generate DC power.

In examples, a hot side of the heat sink 110 to the hot flue gas 106A from the flare, and the cold side of the heat sink 110 faces away from the hot flue gas 106A. In examples, the heat sink is constructed from materials such as concrete, ceramics, or other materials that can withstand temperatures in a range of 1000 F to 1600 F. Additionally, in examples the TEG 112 includes thermoelectric modules made up of multiple thermocouples connected electrically in series and thermally in parallel.

In some embodiments, the TEG 112 is located in close proximity to the heat sink 110 to minimize a length of a transmission line from the heat sink 110 to the TEG 112. In examples, the heat sink 110 and TEG 112 are in close proximity without being physically coupled. In some embodiments, the electrical power generated by the TEG 112 is used to power equipment at the well site, such as local security lighting or batteries located at the well site 100. In this manner, the heat sink 110 and TEG 112 recover heat energy from the atmosphere thereby capturing emissions from flares and creating a sustainable source of energy at the well site 100.

In some embodiments, the heat sink 110 and TEG 112 are strategically positioned near the gas flare. In examples, prevailing winds associated with the location where the well site is located are used to place the heat sink 110 and TEG 112. For example, locating the heat sink 110 and TEG 112 according to the prevailing winds enables the flame to tilt towards the heat sink 110 and TEG 112, thereby increasing the radiant energy that is received from the flare. As shown in the example of FIG. 1, waste heat 106 is directed by winds in the environment towards the heat sink 110 and TEG 112. Waste heat 106A shows the path of the heat as generated by the flare tips 104. Waste heat 106B shows the dissipated heat after traveling across the heat sink 110 and TEG 112.

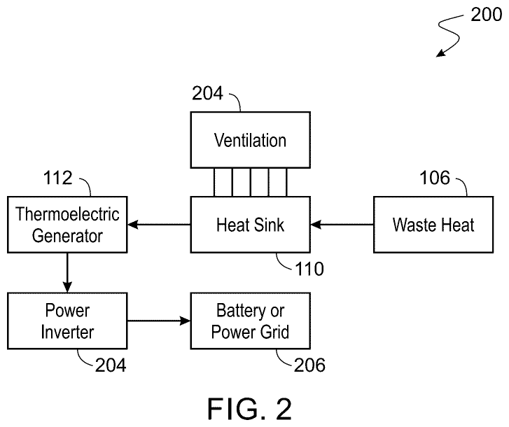

FIG. 2 shows a thermoelectric heat recovery system 200. In examples, the thermoelectric heat recovery system 200 is implemented at the production well 100 of FIG. 1. As shown in the example of FIG. 2, waste heat 106 is obtained by the TEG 112. The waste heat 106 is generated from industrial processes, such as flares. In examples, the waste heat is captured at a hot side of the TEG 112, creating a temperature gradient across the TEG. The heat sink 110 is coupled to a cold side of the TEG 112. The heat absorbed by the hot side is transferred through the TEG to the cold side, generating electricity according to the Seebeck effect. In examples, the Seebeck effect refers to the generation of an electric voltage as a result of a temperature difference between two different conductors or semiconductors. For example, when there is a temperature difference between two junctions of different materials, electrons or charge carriers move from the hot side to the cold side. This movement of charge carriers creates a voltage across the materials. The magnitude of this voltage is proportional to the temperature difference and depends on the materials used.

In examples, a formula for the voltage generated by a thermoelectric material due to a temperature difference according to the Seebeck effect is given by:

$$V = - S Δ T$$

where S represents the Seebeck coefficient, measured in volts per kelvin (V/K), a material property that indicates how much voltage is produced per unit of temperature difference; and ΔT is the temperature difference across the thermoelectric material, measured in kelvin (K) or degrees Celsius (° C.).

The power output from a thermoelectric generator (TEG) can be calculated by the formula:

$$P = I V$$

where P is the power in watts (W) and I is the current in amperes (A) generated due to the voltage V.

Combining with the previous equation, P can also be related to the Seebeck effect and the resistance (R) of the material by:

$$P = \frac{{( S Δ T )}^{2}}{R} , assuming I = \frac{V}{R}$$

The efficiency η of a thermoelectric generator, which is the ratio of the electrical power output to the heat input, can be estimated using the dimensionless figure of merit ZT of the thermoelectric material:

$$η = \frac{{P}_{out}}{{Q}_{in}} = \frac{{S}^{2} Δ {T}^{2}}{{RQ}_{in}}$$

Here, Qᵢₙ represents the heat input into the system. The figure of merit ZT is defined as:

$$ZT = \frac{{S}^{2} σ T}{κ}$$

where σ is the electrical conductivity, T is the average temperature of the thermoelectric material, and κ is the thermal conductivity. Materials with a higher ZT value are more efficient at converting thermal energy into electrical energy.

The heat sink 110 is coupled with or near ventilation 202. In examples, ventilation 202 ensures that the heat sink 110 is cooled by dissipating excess heat, thereby maintaining a lower temperature at the cold side of the TEG. In examples, the ventilation is free ventilation or forced convection ventilation. In free ventilation, natural forces, such as wind, are used to dissipate heat. In examples, warm air rises and cool air sinks, creating a natural flow of wind. In forced ventilation, devices like fans, blowers, or pumps are used to move air to dissipate heat. For example, blowers are used to further cool down the cold side. Maintaining a lower temperature at the cold side of the TEG ensures the creation of a temperature gradient across the TEG 112. In examples, ventilation is moderated to cross the heat sink to change the temperature gradient across the TEG.

The DC power created by the temperature gradient at the TEG 112 is obtained by a power inverter 204. The power inverter 204 processes the DC power and converts it into AC power, integrating seamlessly into existing energy systems. For example, the power inverter 204 takes the DC power from the TEG 112 and uses electronic circuits to switch the DC voltage on and off rapidly, creating a square wave. This square wave is then filtered and modified to produce AC power. The AC power is fed into a battery or power grid at block 206. In examples, the AC power is used to power devices, fed into the power grid, or stored for later use.

In examples, the system 200 also includes sensors and monitoring equipment to track performance metrics such as temperature gradients, power output, and flare intensity. System settings are adjusted based on data collected from monitoring systems to improve efficiency and adapt to changing flare conditions. In examples, system settings include a pre-set range of power output from flaring. If the continuous power output falls below 50% of the input on a daily comparative basis, then troubleshooting or replacement of components of the thermal heat recovery system is performed. For example, batteries (storage) are changed, faulty transmission wires are replaced, or any combinations thereof. In examples, regular inspections and maintenance are performed on the TEGs and heat sinks to ensure optimal performance and address any wear and tear.

In some embodiments, emissions and an environmental impact from the flare are continuously monitored to ensure compliance with regulatory standards. In examples, environmental regulators such as from the Environmental Protection Agency (EPA), Occupational Safety and Health Administration (OSHA) or local municipal authorities have specific requirements on methane releases from flare. In examples, a predetermined flare combustion efficiency is set at 95% or higher. However, carbon dioxide is emitted from combustion. This CO2 emission may be offset by use of heat from flared gas and turning down fuel requirement to run other operating equipment. In particular, the CO2 generated from flare and power grid is removed from the atmosphere, enabling compensation of CO2 emissions.

In some embodiments, safety audits are periodically performed to verify that the thermal heat system's integration with flare operations remains secure and non-intrusive. In examples, integrations with flare operations are secured by monitoring temperatures of the flare using thermocouples of the flare. The source temperature readings indicate the potential radiant heat generated by the flare. The temperature at the flare is compared to the total power generated by the thermal heat recovery system to determine the overall efficiency of the heat transfer. Further, flare operations are secured by ensuring that no intrusion occurs in the flare stack itself which would impede the gas flow through the flare. In examples, any equipment placed on the platforms near the flare are rated to withstand the heat from the flare; otherwise, equipment replacement would require partial shutdown of the plant with turndown on the flare.

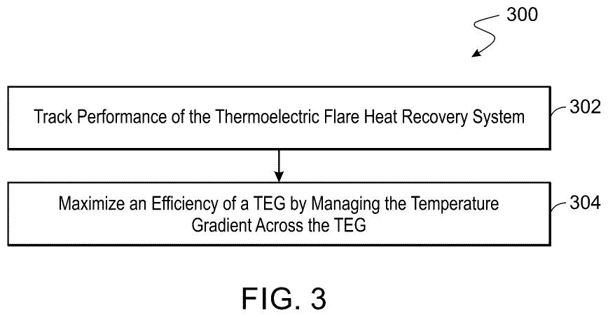

FIG. 3 is a process flow diagram of a process 300 that enables a thermoelectric heat recovery system. In examples, the thermoelectric recovery system described with respect to FIG. 3 is the same as or similar to the thermoelectric recovery system 200 of FIG. 2, and includes components as described with respect to FIG. 1.

At block 302, sensors and monitoring equipment are used to track performance of the thermoelectric flare heat recovery system, where at least one TEG is strategically installed near a gas flare stack. The TEG is coupled with a heat sink. In examples, the sensors include inductive or thermoelectric sensors that measure a temperature change at the exit of the thermoelectric material. When excessive drifts as measured by the sensors are observed, an impact to the performance of the thermoelectric recovery system is likely and operators are notified. In examples, performance is monitored using an empirical algorithm which calculates a theoretical radiative heat from the flare. The theoretical calculation is compared with the actual power generated at start-up, which is serves as a baseline. Subsequent deterioration in performance due to normal wear and tear over time may require material replacement. For example, a reduction of operational efficiency of less than 50% from baseline should trigger root cause analysis, trouble shooting and material replacement.

At block 304, an efficiency of TEGs is maximized by managing the ΔT (e.g., temperature gradient) across the TEG. For example, ventilation is adjusted to increase the temperature gradient, resulting in increased power generation by the TEG. In examples, heat capture from the gas flare is optimized by using materials with high emissivity. Further, heat sinks are configured to effectively dissipate heat on the cold side of the TEG and also minimize thermal losses through insulation. When a gas flare occurs at the gas flare stack, waste heat is captured by the thermoelectric generator and routed to a power storage system or directly to a power grid.

In this manner, the present techniques increase waste heat utilization, and provides additional power generation near gas flares. In some locations where gas flaring occurs, such as remote locations, a thermoelectric heat recovery system satisfies a need for additional electricity. The ability to generate power on-site, which can be particularly valuable in remote areas, enhances energy independence and reducing the need for external power sources.

### Embodiments

According to some non-limiting embodiments or examples, provided is thermoelectric heat recovery system, including: a thermoelectric generator having a hot side and a cold side, where the hot side of the thermoelectric generator is exposed to waste heat emitted by a flare from a well head; a heat sink coupled to the cold side of the thermoelectric generator, where electricity is generated by a temperature gradient across the thermoelectric generator.

According to some non-limiting embodiments or examples, provided is a method, including: monitoring performance of a thermoelectric flare heat recovery system including a thermoelectric generator having a hot side and a cold side, where the hot side of the thermoelectric generator is exposed to waste heat emitted by a flare from a well head and a heat sink coupled to the cold side of the thermoelectric generator; and maximizing an efficiency of the thermoelectric flare heat recovery system by adjusting ventilation from a ventilation system to increase a temperature gradient across the thermoelectric generator, where electricity is generated by the temperature gradient across the thermoelectric generator.

Further non-limiting aspects or embodiments are set forth in the following numbered embodiments:
Embodiment 1: A thermoelectric heat recovery system, including: a thermoelectric generator having a hot side and a cold side, where the hot side of the thermoelectric generator is exposed to waste heat emitted by a flare from a well head; a heat sink coupled to the cold side of the thermoelectric generator, where electricity is generated by a temperature gradient across the thermoelectric generator.
Embodiment 2: The thermoelectric heat recovery system of any preceding embodiment, where a ventilation system cools the heat sink and is powered by the thermoelectric generator.
Embodiment 3: The thermoelectric heat recovery system of any preceding embodiment, including sensors and monitoring equipment that capture data associated with the performance of the thermoelectric heat recovery system.
Embodiment 4: The thermoelectric heat recovery system of any preceding embodiment, including at least one battery that stores electricity generated by the temperature gradient across the thermoelectric generator.
Embodiment 5: The thermoelectric heat recovery system of any preceding embodiment, where the thermoelectric generator is strategically positioned at the well head according to prevailing winds associated with a location of the well head.
Embodiment 6: The thermoelectric heat recovery system of any preceding embodiment, where the heat sink is constructed from concrete or ceramic, and can withstand temperatures in a range of 1000 F to 1600 F.
Embodiment 7: The thermoelectric heat recovery system of claim 1, where the thermoelectric generator is located with respect to the heat sink to minimize a length of a transmission line from the thermoelectric generator to the heat sink.
Embodiment 8: A method, including: monitoring performance of a thermoelectric flare heat recovery system including a thermoelectric generator having a hot side and a cold side, where the hot side of the thermoelectric generator is exposed to waste heat emitted by a flare from a well head and a heat sink coupled to the cold side of the thermoelectric generator; and maximizing an efficiency of the thermoelectric flare heat recovery system by adjusting ventilation from a ventilation system to increase a temperature gradient across the thermoelectric generator, where electricity is generated by the temperature gradient across the thermoelectric generator.
Embodiment 9: The method of any preceding embodiment, where the ventilation system is powered by the thermoelectric generator.
Embodiment 10: The method of any preceding embodiment, where the performance is based on data captured by inductive or thermoelectric sensors that measure a temperature change at the thermoelectric generator.
Embodiment 11: The method of any preceding embodiment, including at least one battery that stores electricity generated by the temperature gradient across the thermoelectric generator.
Embodiment 12: The method of any preceding embodiment, where the thermoelectric generator is strategically positioned at a well head according to prevailing winds associated with a location of the well head.
Embodiment 13: The method of any preceding embodiment, where the heat sink is constructed from concrete or ceramic, and can withstand temperatures in a range of 1000 F to 1600 F.
Embodiment 14: The method of any preceding embodiment, where the thermoelectric generator is located with respect to the heat sink to minimize a length of a transmission line from the thermoelectric generator to the heat sink.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation.

Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular embodiments of the subject matter have been described. Other embodiments are within the scope of the following claims. For example, the actions recited in the claims can be performed in a different order and still achieve desirable results. As one example, some processes depicted in the accompanying figures do not necessarily require the particular order shown, or sequential order, to achieve desirable results.

1. A thermoelectric heat recovery system, comprising:
a thermoelectric generator having a hot side and a cold side, wherein the hot side of the thermoelectric generator is exposed to waste heat emitted by a flare from a well head;
a heat sink coupled to the cold side of the thermoelectric generator, wherein electricity is generated by a temperature gradient across the thermoelectric generator; and
a power inverter that captures the electricity generated by the temperature gradient across the thermoelectric generator, wherein the power inverter uses electronic circuits to produce alternating current (AC) power that powers local security lighting at a well site including the well head.

2. The thermoelectric heat recovery system of claim 1, wherein a ventilation system cools the heat sink and is powered by the thermoelectric generator.

3. The thermoelectric heat recovery system of claim 1, comprising sensors and monitoring equipment that capture data associated with a performance of the thermoelectric heat recovery system.

4. The thermoelectric heat recovery system of claim 1, comprising at least one battery that stores electricity generated by the temperature gradient across the thermoelectric generator.

5. The thermoelectric heat recovery system of claim 1, wherein the thermoelectric generator is positioned at the well head according to prevailing winds associated with a location of the well head.

6. The thermoelectric heat recovery system of claim 1, wherein the heat sink is constructed from concrete or ceramic, and can withstand temperatures in a range of 1000 F to 1600 F.

7. The thermoelectric heat recovery system of claim 1, wherein the thermoelectric generator is located with respect to the heat sink to minimize a length of a transmission line from the thermoelectric generator to the heat sink.

8. A method, comprising:
monitoring performance of a thermoelectric flare heat recovery system comprising a thermoelectric generator having a hot side and a cold side, wherein the hot side of the thermoelectric generator is exposed to waste heat emitted by a flare from a well head and a heat sink coupled to the cold side of the thermoelectric generator; and
maximizing an efficiency of the thermoelectric flare heat recovery system by adjusting ventilation from a ventilation system to increase a temperature gradient across the thermoelectric generator, wherein electricity is generated by the temperature gradient across the thermoelectric generator.

9. The method of claim 8, wherein the ventilation system is powered by the thermoelectric generator.

10. The method of claim 8, wherein the performance is based on data captured by inductive or thermoelectric sensors that measure a temperature change at the thermoelectric generator.

11. The method of claim 8, comprising at least one battery that stores electricity generated by the temperature gradient across the thermoelectric generator.

12. The method of claim 8, wherein the thermoelectric generator is strategically positioned at the well head according to prevailing winds associated with a location of the well head.

13. The method of claim 8, wherein the heat sink is constructed from concrete or ceramic, and can withstand temperatures in a range of 1000 F to 1600 F.

14. The method of claim 8, wherein the thermoelectric generator is located with respect to the heat sink to minimize a length of a transmission line from the thermoelectric generator to the heat sink.
